(19) United States
(12) Patent Application Publication
(10) Pub. No.: US 2022/0013481 A1
(43) Pub. Date: Jan. 13, 2022

(54) SEMICONDUCTOR DEVICE AND METHOD OF MANUFACTURING THE SAME

(71) Applicant: RENESAS ELECTRONICS CORPORATION, Tokyo (JP)

(72) Inventor: Tatsuya USAMI, Tokyo (JP)

(21) Appl. No.: 16/927,331

(22) Filed: Jul. 13, 2020

(51) Int. Cl. H01L 23/00; H01L 23/31

(52) U.S. Cl. CPC H01L 24/05; H01L 23/3142; H01L 24/48; H01L 24/03; H01L 2224/0221; H01L 2224/02181; H01L 2224/48091; H01L 2224/02125; H01L 2224/04042; H01L 2224/05624; H01L 2224/48465; H01L 2224/0311; H01L 2224/0312; H01L 2224/05573

(57) ABSTRACT

A groove is formed between an inner peripheral edge of an opening of a pad electrode and an outer peripheral edge of a bonding region located inside the pad electrode in plan view.

### BACKGROUND

Recently, as a structure of semiconductor devices has become finer and more highly integrated, an importance of low-resistivity wiring has been increasing. Along with it, Cu (copper), which has a relatively low resistance, is adapted to be often used as a wiring material. Further, a so-called Low-k film (k<3.0) having a low dielectric constant k is often used as an interlayer insulating film. On the other hand, a pad electrode is usually formed simultaneously with a top layer metallic wiring. Then, a bonding wire is connected to the pad electrode. Specifically, by a method such as ultrasonic or thermocompression bonding to the pad electrode, a gold (Au) wire or a copper (Cu) wire is bonded.

Here, a load or an impact force applied during wire bonding deforms the pad electrode and is directly transmitted to a surface protective film around the pad electrode and the interlayer insulating film. Then, there is a problem that cracks occur in the surface protective film and the interlayer insulating film. Since the surface protective film around the pad electrode includes a film having a relatively low fracture toughness, the cracks tend to occur in the surface protective film. Further, since a mechanical strength is about one order of magnitude lower than a silicon oxide film (SiO2) when the interlayer insulating film is a Low-k film, the cracks tend to occur in the interlayer insulating film. Furthermore, if the bonding wire is the copper (Cu) wire, the impact force applied during wire bonding is increased. A reason is that the copper (Cu) wire has higher hardness than the gold (Au) wire. As a result, in the case of the copper (Cu) wire, the cracks occur in the surface protective film around the pad electrode and the interlayer insulating film becomes more remarkable.

JP-A-2018-74063 (Patent Document 1) discloses a technique for absorbing a bonding impact by forming a plurality of voids in the pad electrode made of aluminum. However, in the technique described in Patent Document 1, a region where the plurality of voids are not formed, that is, an around of an upper surface of the pad electrode, or the portion where the voids are not formed between the upper surface of the pad electrode and the interlayer insulating film. It may not be able to fully absorb a deformation of the pad electrode. As a result, the load or the impact force applied at the time of wire bonding in these locations is directly transmitted to the protective surface film and the interlayer insulating film around the pad electrode, there is a possibility that the cracks occur in the protective surface film and the interlayer insulating film. Therefore, semiconductor device described in Patent Document 1 can be improved from the viewpoint of preventing the cracks in the protective surface film and the interlayer insulating film at the time of wire bonding.

### SUMMARY

The problem of present embodiments, it is to prevent the cracks in the surface protective film and the interlayer insulating film around the pad electrode at the time of wire bonding.

According to embodiments, in the pad electrode, a groove is formed between an inner peripheral edge of an opening of the pad electrode and an outer peripheral edge of a bonding area, and the groove penetrates a part of the pad electrode.

According to the embodiments, it is possible to prevent the cracks in the surface protective film and the interlayer insulating film around the pad electrode. As the result, it is possible to improve a reliability of the semiconductor device.

Other objects and novel features will become apparent from the description of this specification and the accompanying drawings.

### BRIEF DESCRIPTION OF THE DRAWINGS

FIG. 1 is a plan view showing an exemplary configuration of a semiconductor device according to a first embodiment.

FIG. 2 is a cross-sectional view showing an exemplary configuration of the semiconductor device according to the first embodiment.

FIG. 3 is a main portion plan view showing the pad electrode and its periphery of the semiconductor device according to the first embodiment.

FIG. 4 is a main portion cross-sectional view showing the pad electrode and its periphery of the semiconductor device according to the first embodiment.

FIG. 5 is a cross-sectional view showing an exemplary process step included in a manufacturing method of the semiconductor device according to the first embodiment.

FIG. 6 is a cross-sectional view showing an exemplary process step included in the manufacturing method of the semiconductor device according to the first embodiment.

FIG. 7 is a cross-sectional view showing an exemplary process step included in the manufacturing method of the semiconductor device according to the first embodiment.

FIG. 8 is a cross-sectional view showing an exemplary process step included in the manufacturing method of the semiconductor device according to the first embodiment.

FIG. 9 is a cross-sectional view showing an exemplary process step included in the manufacturing method of the semiconductor device according to the first embodiment.

FIG. 10 is a cross-sectional view showing an exemplary process step included in the manufacturing method of the semiconductor device according to the first embodiment.

FIG. 11 is a cross-sectional view showing an exemplary process step included in the manufacturing method of the semiconductor device according to the first embodiment.

FIG. 12 is a cross-sectional view showing an exemplary process step included in the manufacturing method of the semiconductor device according to the first embodiment.

FIG. 13 is a main portion cross-sectional view showing a state where the bonding wire is connected to the pad electrode of semiconductor device according to the first embodiment.

FIG. 14 is a main portion cross-sectional view showing a state where a semiconductor chip is filled with a sealing body according to the first embodiment.

FIG. 15 is a main portion cross-sectional view showing the pad electrode and its periphery of the semiconductor device according to a second embodiment.

FIG. 16 is a main portion cross-sectional view showing the pad electrode and its periphery of the semiconductor device according to a third embodiment.

FIG. 17 is a main portion cross-sectional view showing the pad electrode and its periphery of the semiconductor device according to a fourth embodiment.

FIG. 18 is a main portion cross-sectional view showing the pad electrode and its periphery of the semiconductor device according to a fifth embodiment.

### DETAILED DESCRIPTION

In the following embodiments, where it is necessary for convenience, they shall be explained by dividing them into multiple sections or embodiments, but they shall not be related to each other unless otherwise explicitly indicated. In the following embodiments, reference to the number of elements or the like (including the number, numerical value, quantity, range, and the like) is not limited to the specific number, and may be greater than or equal to the specific number or less, except in the case where it is specifically specified and the case where it is obviously limited to the specific number in principle.

Furthermore, in the following embodiments, the constituent elements (including element steps and the like) are not necessarily essential except in the case where they are specifically specified and the case where they are considered to be obviously essential in principle. Similarly, in the following embodiments, reference to shapes, positional relationships, and the like of constituent elements and the like includes substantially approximate or similar shapes and the like, except for the case in which they are specifically specified and the case in which they are considered to be obvious in principle and the like. The same applies to the above-mentioned numbers and the like, including the number, the numerical value, the amount, the range, and the like.

In all the drawings for explaining the embodiments, members having the same function are denoted by the same or related reference numerals, and repetitive description thereof is omitted. In addition, when there are a plurality of similar members (portions), symbols may be added to the generic term reference numerals to indicate individual or specific portions. In the following embodiments, descriptions of the same or similar parts will not be repeated in principle except when particularly necessary.

In the drawings used in the embodiments, hatching may be omitted even in the case of cross-sectional view in order to make the drawings easier to see. In addition, even plan view may be hatched to make the drawings easier to understand. Also, in cross-sectional view and plan view, the size of each part does not correspond to the actual device. In addition, in some cases, a specific site is displayed relatively large for clarity of the drawings. In addition, even when cross-sectional view and plan view correspond to each other, a particular portion may be displayed relatively large in order to make the drawing easy to understand.

### First Embodiment

(Structure)

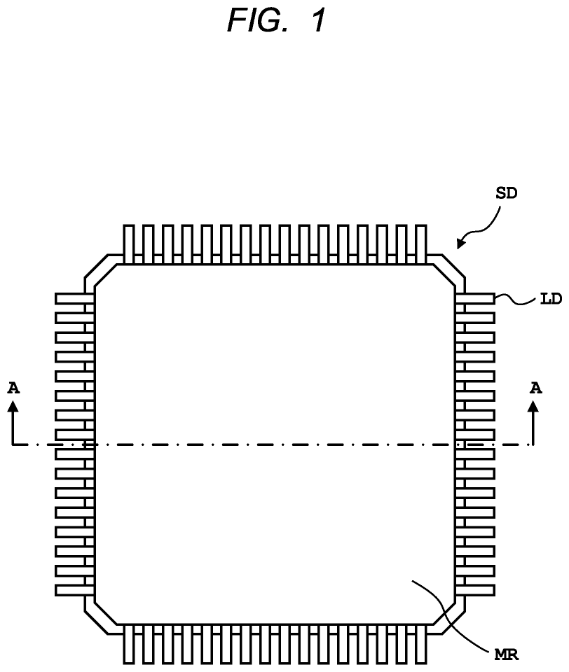

FIG. 1 is a plan view showing an entire semiconductor device according to the first embodiment. As shown in FIG. 1, a semiconductor device SD of the first embodiment is a semiconductor device in the form of a resin-sealed semiconductor package, for example, a semiconductor device in the form of QFP (Quad Flat Package). A semiconductor package form is not limited to QFP, and the semiconductor package may be, for example, SOP (Small Outline Package) form or another form.

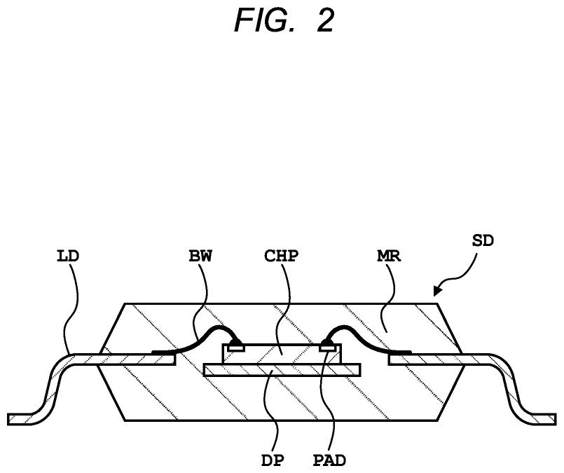

FIG. 2 is a cross-sectional view showing an exemplary configuration of the semiconductor device according to the first embodiment in the A-A section shown in FIG. 1. As shown in FIG. 2, the semiconductor device SD of the first embodiment includes a semiconductor chip CHP, a die pad DP for supporting or mounting the semiconductor chip CHP, a plurality of leads LD formed by conductor, a plurality of bonding wires BW for electrically connecting one end of the plurality of leads LD and a plurality of pad electrodes PAD formed on an upper surface of the semiconductor chip CHP respectively, and a sealing body MR for sealing them.

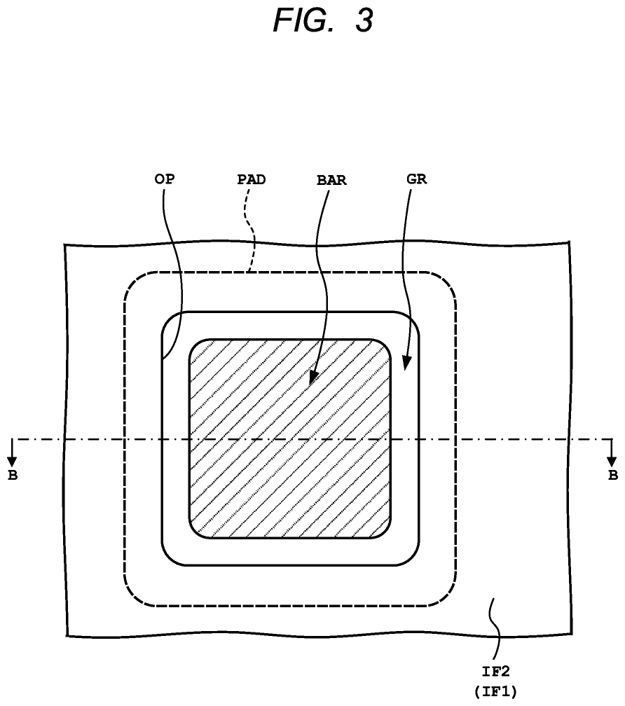

FIG. 3 is a main portion plan view showing the pad electrode PAD and its periphery of the semiconductor device SD. FIG. 3 shows the pad electrode PAD representing one of a plurality of pad electrodes having the semiconductor chip CHP. It is similar in figures after FIG. 3.

As shown in FIG. 3, the pad electrode PAD is substantially rectangular in plan view. A length of one side of the pad electrode PAD is about 50 μm to 200 μm. The pad electrode PAD is covered with a laminated film composed of a first surface protective film IF1 and a second surface protective film IF2. The laminated film has an opening OP so that a part of the pad electrode PAD is exposed. A length of one side of the opening OP is shorter than a length of one side of the pad electrode PAD. An upper surface of the pad electrode PAD inside the opening OP has a bonding region BAR which is an area for bonding the bonding wire BW (hatched portion). Then, A groove GR in which a part of the pad electrode PAD is removed is formed between an inner peripheral edge of the opening OP and an outer peripheral edge of the bonding region BAR. The groove GR is formed so as to surround the outer peripheral edge of the bonding region BAR. Further, the groove GR is formed along the inner peripheral edge of the opening OP. Here, a first direction is extending along the outer peripheral edge of the bonding region BAR, a width of the groove GR in a second direction orthogonal to the first direction is 2 μm or more, 10 μm or less.

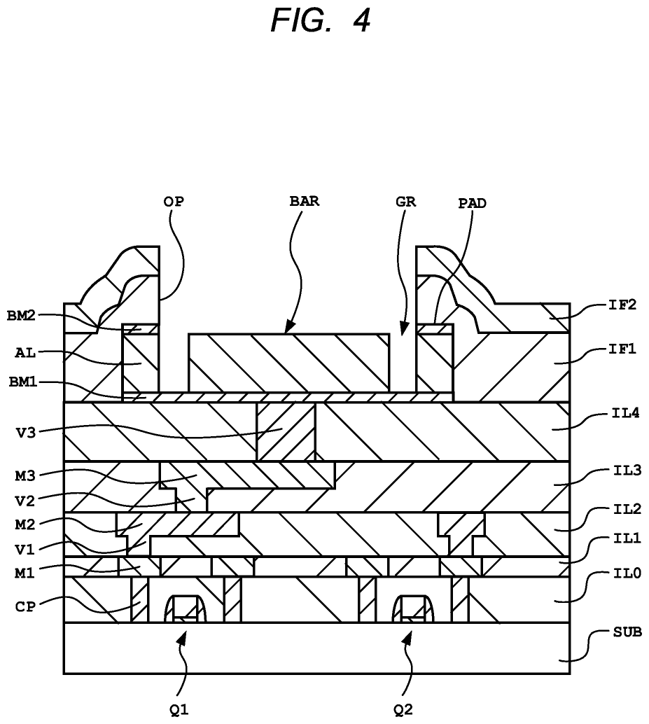

FIG. 4 is a main portion cross-sectional view corresponding to the B-B cross-section of FIG. 3.

The structure of a third wiring M3 and its upper layer in the first embodiment will be described with reference to FIG. 4. The pad electrode PAD is formed on an interlayer insulating film IL4 formed on the third wiring M3 and on a plug (via) V3 penetrating the interlayer insulating film IL4. That is, the interlayer insulating film IL4 is formed so as to contact with a bottom surface of the pad electrode. The third wiring M3 is composed of a conductive film mainly composed of copper (Cu). The interlayer insulating film IL4 is composed of, for example, a silicon oxide film, a silicon oxide film to which fluorine added (SiOF), or a Low-k film. The pad electrode PAD includes a first barrier metal film BM1, a conductive film AL, and a second barrier metal film BM2 is constituted by a laminated film laminated in this order. The pad electrode PAD is electrically connected to the plug (via) V3.

The conductive film AL is made of, for example, a material containing aluminum as a main component. Specifically, it is made of an aluminum film, or an aluminum-alloy film (Al—Si film, Al—Si—Cu film, or the like). A thickness of the conductive film AL is about 1.5 μm to 9.5 μm.

The first barrier metal film BM1 and the second barrier metal film BM2 are made of, for example, a material containing titanium nitride as a main component. Specifically, it is formed of a titanium nitride film or a laminated film of the titanium nitride film and a titanium film. A thickness of each of the first barrier metal film BM1 and the second barrier metal film BM2 are about 100 nm to 300 nm.

Here, the second barrier metal film BM2 can be omitted from the laminated film constituting the pad electrode PAD. Since the second barrier metal film BM2 is removed from the bonding region BAR, a function of the bonding region BAR as the pad electrode PAD is not affected even if the second barrier metal film BM2 is not formed in the bonding region BAR.

On the interlayer insulating film IL4, the laminated film in which the first surface protective film IF1 and the second surface protective film IF2 are laminated in this order is formed so as to cover the pad electrode PAD.

A first protective film IF1 is made of, for example, the silicon oxide film or a silicon nitride film. The second surface protective film IF2 is made of, for example, an organic resin film such as a polyimide film. The first protective film IF1 may be a silicon oxynitride film or a silicon oxycarbide film. The second surface protective film IF2 may be the silicon nitride film in addition to the silicon nitride film.

However, since the first surface protective film IF1 is embedded between a plurality of pad electrodes PAD, it is preferable to apply a forming method and a material having good embeddability. The silicon oxide film formed by HDP-CVD (High-Density Plasma Chemical Vapor Deposition) method has an advantage of good embeddability. On the other hand, since the second surface protective film IF2 functions as a passivating film for protecting a surface of the semiconductor device SD, it is preferable to apply a material having a high step coverage. The polyimide film has an advantage of good function as passivation film due to their high step coverage performance. Note that, in the first embodiment, a configuration in which the surface protective film is the laminated film of two layers has been described, but a configuration of a single layer may be used, and a configuration of three or more layers may be used.

A thickness of the first protective film IF1 is about 300 nm to 2 μm. And a thickness of the second surface protective film IF2 is about 2 μm to 5 μm.

The laminated film composed of the first surface protective film IF1 and the second surface protective film IF2 has the opening OP which is partially exposed on the pad electrode PAD. That is, the opening OP has reached the upper surface of the pad electrode PAD through the laminated film. More specifically, the opening OP has reached an upper surface of the conductive film AL of the pad electrode PAD through the laminated film and the second barrier metal film BM2. On the other hand, an end portion of the pad electrode PAD is covered with the laminated film.

An upper surface of the pad electrode PAD in the opening OP, that is, the upper surface of the conductive film AL has the bonding region BAR which is an area for bonding the bonding wire BW.

The conductive film AL is exposed in the bonding region BAR. In other words, the second barrier metal film BM2 of the pad electrode PAD is removed from the pad electrode PAD in the bonding region BAR. Then, the bonding wire BW (not shown) is connected to the bonding region BAR.

In order to improve a reliability of the junction between the bonding wire BW and the pad electrode PAD, a palladium (Pd) layer, a gold (Au) layer, or a nickel (Ni) layer may be provided between the bonding wire BW and the upper surface of the pad electrode PAD (the upper surface of the conductive film AL).

As shown in FIG. 4, the groove GR in which a part of the pad electrode PAD is removed is formed in the opening OP. Positions of both side surfaces of the groove GR correspond to the outer peripheral edge of the bonding region BAR and the inner peripheral edge of the opening OP, respectively. the groove GR is formed so as to surround the bonding region BAR. That is, the groove GR is located in the opening OP, and the groove GR is not covered with the laminated film composed of the first surface protective film IF1 and the second surface protective film IF2. Further, the groove GR penetrates the conductive film AL, and reaches an upper surface of the first barrier metal film BM1. In other words, the upper surface of the first barrier metal film BM1 is exposed at a bottom of the groove GR.

(Manufacturing Method of the Semiconductor Device According to the First Embodiment)

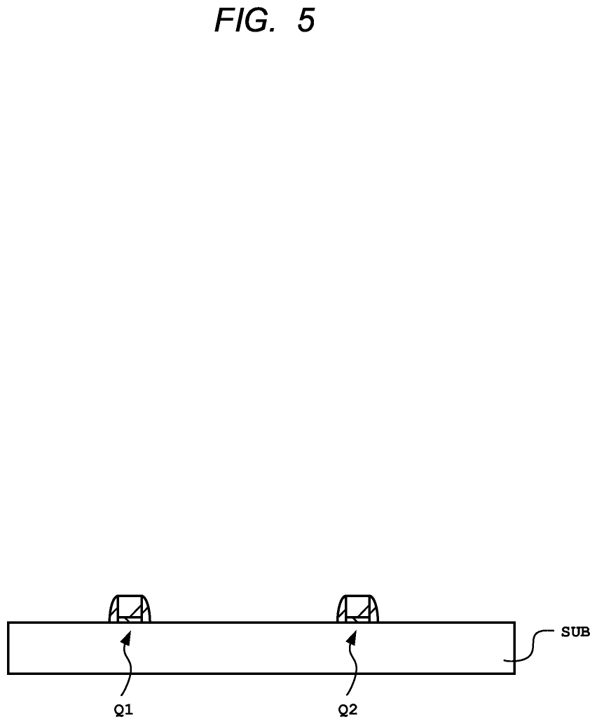

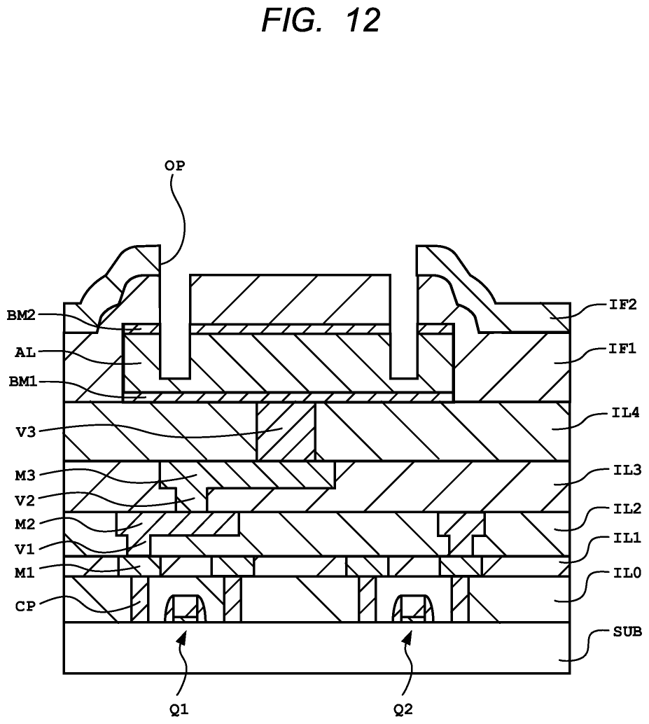

Next, an exemplary manufacturing method of the semiconductor device SD according to the first embodiment will be described. FIG. 5 to FIG. 12 are cross-sectional views showing an exemplary process steps included in a manufacturing method of the semiconductor device SD according to the first embodiment.

First, as shown in FIG. 5, to prepare a semiconductor substrate (semiconductor wafer) SUB made of, for example, p-type single crystal silicon. Next, A plurality of element isolation portions (not shown) defining active regions are formed in the semiconductor substrate SUB. The element isolation portions are formed by, for example, embedding an insulating film mainly made of silicon oxide in a trench formed in the semiconductor substrate SUB.

Subsequently, after introducing impurities into the semiconductor substrate SUB to form well (not shown), a MISFETQ1 and a MISFETQ2 comprising a gate electrode formed on the well (not shown) through a gate dielectric film and a source-drain region formed in the well (not shown), respectively.

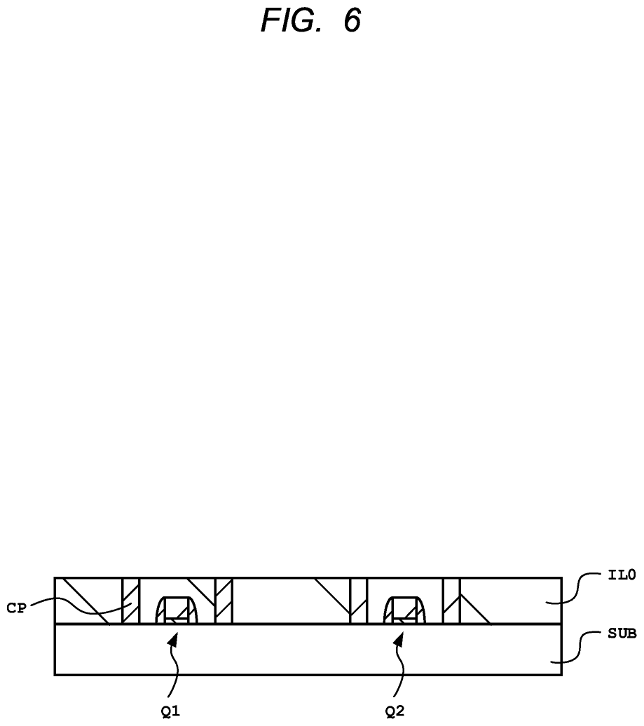

Subsequently, as shown in FIG. 6, to form an interlayer insulating film IL0 covering the semiconductor substrate SUB and the gate electrodes. The interlayer insulating film IL0 is made of, for example, the silicon oxide film. Thereafter, a contact holes are formed in the interlayer insulating film IL0 using a photolithography technique and a dry etching method. Thereafter, in the contact holes, forming contact plugs CP by embedding, for example, a barrier conductor film containing titanium (Ti) or titanium nitride (TiN), and for example, a main conductor film made of tungsten (W). The contact plugs CP are connected to the MISFETQ1, the MISFETQ2, or the like.

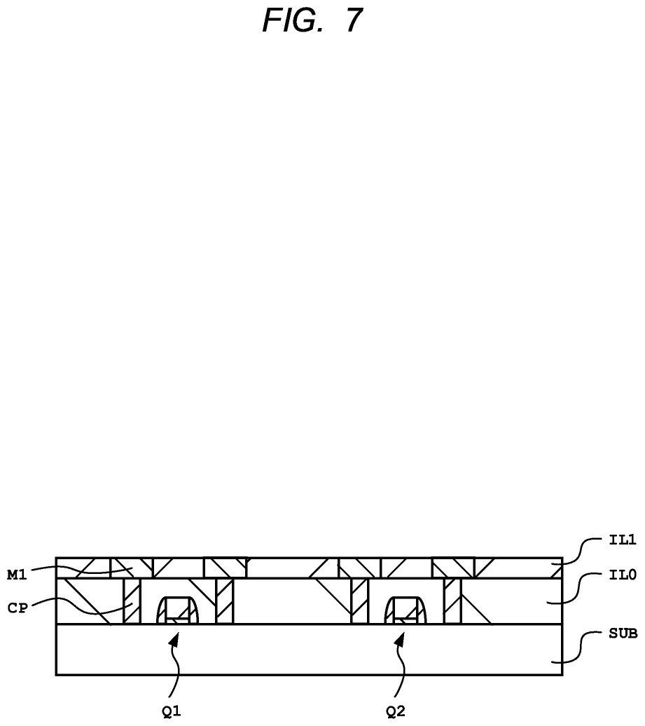

Subsequently, as shown in FIG. 7, to form an interlayer insulating film IL1 on the interlayer insulating film IL0 in which the contact plugs CP are embedded. The interlayer insulating film IL1 is made of a material having a dielectric constant lower than that of silicon oxide, for example, silicon oxide containing carbon such as SiOC. A first wiring M1 is formed using damascene technique. That is, the first wiring M1 is formed by forming a trench in the interlayer insulating film IL1, forming a conductive film containing copper, and removing the conductive film formed an outside of the trench using the CMP (Chemical Mechanical Polishing) method. Incidentally, a barrier insulating film made of, for example, silicon carbonitride, which has a function of preventing diffusion of copper, is formed between the conductive film and the interlayer insulating film IL1, but an illustration thereof is omitted here. The first wiring M1 is connected to an upper surface of the contact plugs CP.

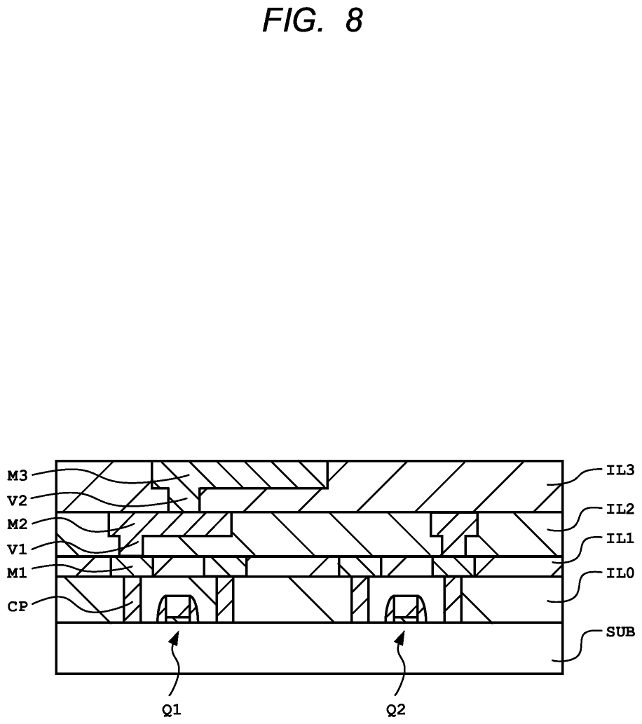

Subsequently, as shown in FIG. 8, an interlayer insulating film IL2 is formed on the interlayer insulating film IL1 so as to cover the first wiring M1. The interlayer insulating film IL2 is composed of a same material as the interlayer insulating film IL1. In addition, a barrier insulating film for preventing copper from diffusing may be formed on upper surface of the first wiring M1. Next, a plug (via) V1 and the second wiring M2 is formed by forming via hole and trench in the interlayer insulating film IL2 and embedding, for example, a conductive film containing copper in the via hole and the trench using a CMP method. That is, the plug (via) V1 and the second wiring M2 are formed by a dual damascene method, which is one type of damascene method, and they are integrated. Incidentally, a barrier insulating film for preventing copper from diffusing may be formed between the second wiring M2 and the interlayer insulating film IL2. The plug (via) V1 is connected to an upper surface of the first wiring M1.

Thereafter, by repeating the same process, an interlayer insulating film IL3, a plug (via) V2, and the third wiring M3 are formed. As a result, the multilayer wiring structure shown in FIG. 8 is formed. Note that, repeated description is omitted here.

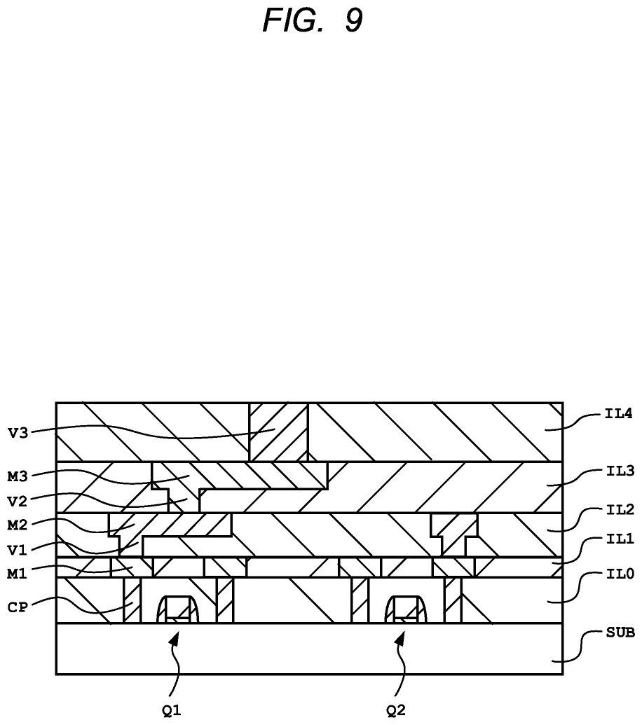

Next, as shown in FIG. 9, the interlayer insulating film IL4 is formed on the interlayer insulating film IL3 so as to cover the third wiring M3. The interlayer insulating film IL4 is composed of, for example, the silicon oxide film, a fluorine-added silicon oxide film, or a Low-k film. Thereafter, a via hole is formed in the interlayer insulating film IL4 by using a photolithography technique and a dry etching method.

Subsequently, the plug (via) V3 is formed by embedding, for example, a barrier conductor film containing titanium (Ti) or titanium nitride (TiN), and for example, a main conductor film made of tungsten (W). The plug (via) V3 is connected to an upper surface of the third wiring M3.

Subsequently, the first barrier metal film BM1, the conductive film AL, and the second barrier metal film BM2 are sequentially stacked by a CVD method or a sputtering method.

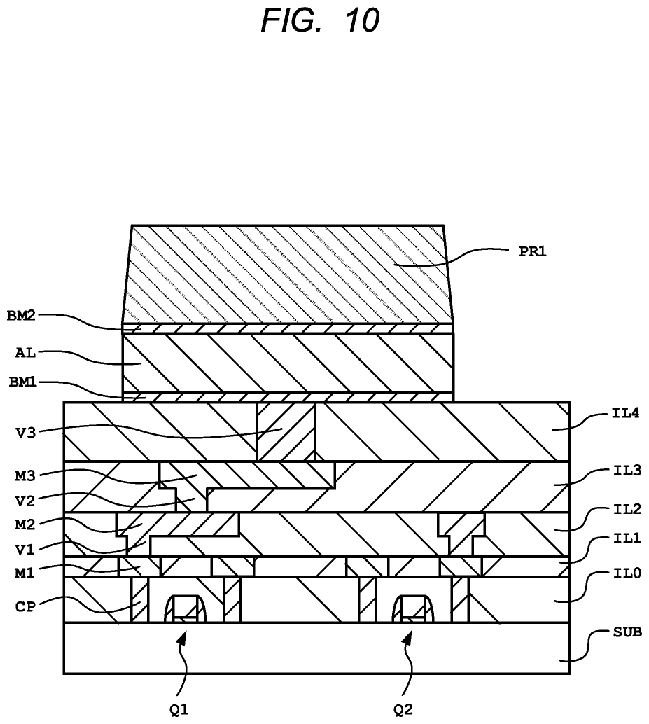

Next, as shown in FIG. 10, a photoresist pattern PR1 is formed on the second barrier metal film BM2 by a photolithography technique. The photoresist pattern PR1 is a pattern for forming the pad electrode PAD.

Subsequently, by performing a dry etching process using the photoresist pattern PR1 as a mask, the second barrier metal film BM2, the conductive film AL and the first barrier metal film BM1 are sequentially removed. Thus, the interlayer insulating film IL4 other than the region where the pad electrode PAD is formed is exposed. As a result, the pad electrode PAD is formed.

Next, after the photoresist pattern PR1 is removed by ashing, the first surface protective film IF1 is formed on the interlayer insulating film IL4 so as to cover the pad electrode PAD. The first surface protective film IF1 is an insulating film formed by using, for example, the HDP-CVD method, and is made of, for example, the silicon oxide film or the silicon nitride film.

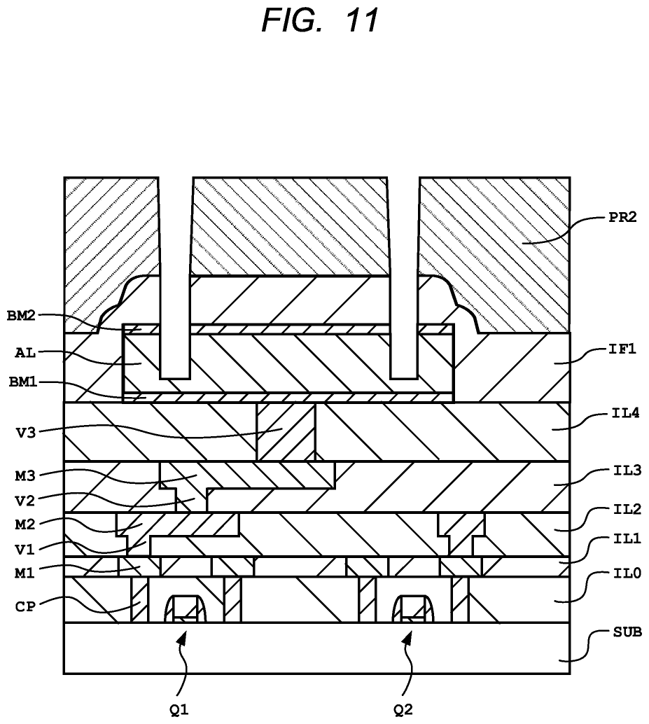

Next, as shown in FIG. 11, a photoresist pattern PR2 is formed on the first surface protective film IF1 by a photolithography technique. The photoresist pattern PR2 is a pattern for forming the groove GR.

Subsequently, by performing a dry etching process using the photoresist pattern PR2 as a mask, the first surface protective film IF1, the second barrier metal film BM2 and a part of the conductive film AL are sequentially removed. At this time, a groove formed by the dry etching process penetrates the first surface protective film IF1 and the second barrier metal film BM2, but does not penetrate the conductive film AL. That is, the dry etching process is finished in a middle of the conductive film AL.

Next, after the photoresist pattern PR2 is removed by ashing, the second surface protective film IF2 is formed on the first surface protective film IF1 so as to cover the pad electrode PAD. The second surface protective film IF2 is made of, for example, the organic resin film such as the polyimide film. The polyimide film is formed, for example, by spin coating a photosensitive polyimide precursor solution and drying them. The polyimide film on the pad electrode PAD is partially removed by exposing and developing the polyimide film. And a heat treatment is performed to cure the polyimide film. As the result, the opening OP is formed.

Subsequently, by performing a dry etching process using the second surface protective film IF2 as a mask, the first surface protective film IF1 and the second barrier metal film BM2 in the opening OP, the conductive film AL in the groove GR are removed. By the dry etching process, the conductive film AL is exposed in the opening OP, penetrates the conductive film AL and exposes the upper surface of the first barrier metal film BM1 in the groove GR. At this time, a part of the first barrier metal film BM1 may be removed by over etching in the groove GR. Incidentally, in the opening OP, a region where the conductive film AL is exposed becomes the bonding region BAR.

Through the above steps, the structure shown in FIG. 3 is formed.

After that, in post process steps, the semiconductor substrate SUB is divided a plurality of the semiconductor chips CHP by dicing or the like, and then, arranged on the die pad DP of a lead frame. after that, the pad electrode PAD and one end of the lead LD is connected by the bonding wire BW. Next, sealing body MR is formed so as to cover the semiconductor chip CHP and the bonding wire BW. The sealing body MR is made of, for example, an epoxy resin, and contains, for example, a reactant of a silane coupling agent.

Through the above steps, the semiconductor device SD of the first embodiment is manufactured.

(Effects of the First Embodiment)

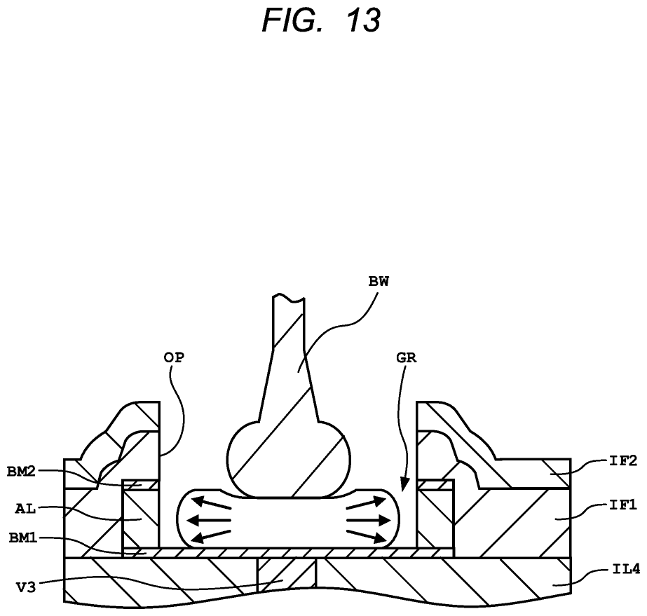

FIG. 13 is a diagram showing a state in which the bonding wire BW is connected to the pad electrode PAD in a structure of the first embodiment. The arrows shown in FIG. 13 schematically show how the upper surface of the conductive film AL is recessed and side surfaces are deformed by a load or an impact applied during wire bonding.

The periphery of the pad electrode PAD is covered with the first surface protective film IF1. The first protective film IF1 is, for example, the silicon oxide film or the silicon nitride film. These films have low fracture toughness, for this reason, when the load or the impact applied at the time of wire bonding is directly transmitted to the first surface protective film IF1, there is a problem that cracks occur in the first surface protective film IF1. In particular, a portion of the first surface protective film IF1 covering an end portion of the pad electrode PAD is easily cracked. This is because a thickness of the portion of the first surface protective film IF1 is locally thin.

Here, it can be considered that the groove GR is formed in the pad electrode PAD outside the inner peripheral edge of the opening OP, that is, in the region where the pad electrode PAD is covered with the first surface protective film IF1. However, in this case, the bonding region BAR and the first surface protective film IF1 are in contact with each other. Therefore, the load or the impact applied during wire bonding is directly transmitted to the first surface protective film IF1. As the results, the cracks occur in the portion of the first surface protective film IF1 covering the end portion of the pad electrode PAD.

For the above reason, it is preferable to form the groove GR between the inner peripheral edge of the opening OP and the outer peripheral edge of the bonding region BAR. In this structure, it is possible to block the impact applied during wire bonding to the end portion of the pad electrode PAD. Then, it is possible to prevent the impact from being transmitted to the first surface protective film IF1.

The impact applied during wire bonding is transmitted to the interlayer insulating film IL3 via the interlayer insulating film IL4 and the plug (via) V3 which are in contact with a bottom of the pad electrode PAD. However, by forming the groove GR so as to surround a periphery of the bonding region BAR along the inner peripheral edge of the opening OP, side surfaces of the conductive film AL are released by the groove GR. As a result, the conductive film AL has a structure that can be elastically deformed in a horizontal direction. It is possible to reduce the transmission of the impact in a thickness direction of the conductive film AL by absorbing the impact applied at the time of wire bonding by elastic deformation.

Also, in this case, the groove GR is preferably formed between the inner peripheral edge of the opening OP and the outer peripheral edge of the bonding region BAR. This is because the groove GR is not covered with the first surface protective film IF1 and the side surfaces of the conductive film AL is completely opened.

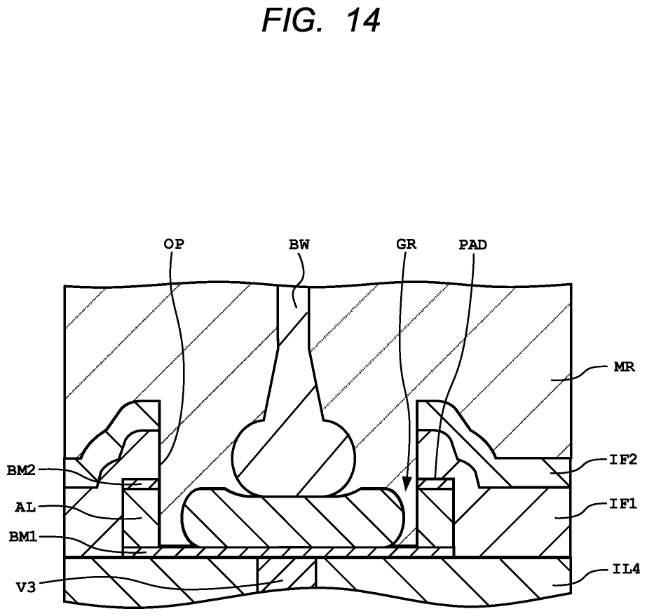

FIG. 14 is a main portion cross-sectional view showing a state where a semiconductor chip is filled with the sealing body MR according to the first embodiment. As shown in FIG. 14, when the sealing body MR is formed, the groove GR is also filled with a material of the sealing body MR. Since the groove GR is not covered with the laminated film composed of the first surface protective film IF1 and the second surface protective film IF2, the groove GR can be filled with the material of the sealing body MR when the sealing body MR is formed. Here, if a gap is formed in the pad electrode PAD and its periphery, moisture easily enters the pad electrode PAD through the gap. Moisture causes the pad electrode PAD to corrode, reducing the reliability of the semiconductor device SD. On the other hand, in the semiconductor device SD of the first embodiment, the material of the sealing body MR is also filled in the groove GR, so that no gap can be formed in the pad electrode PAD and its periphery. Therefore, it is possible to prevent the reliability of the semiconductor device SD from deteriorating.

### Second Embodiment

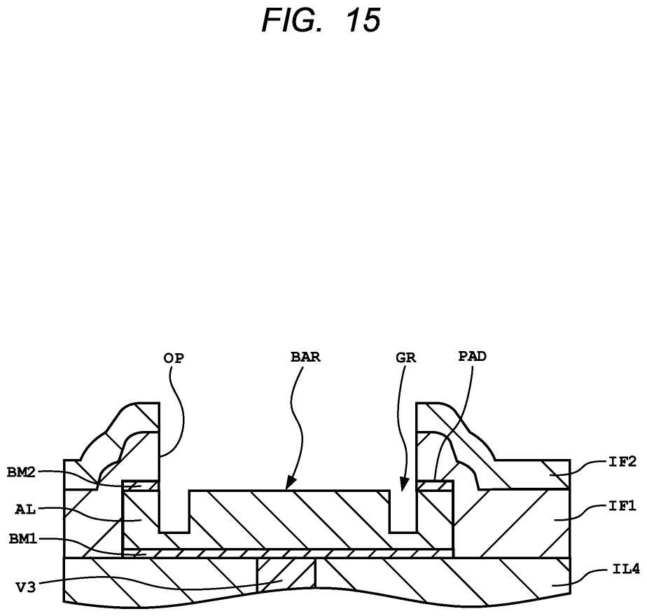

Hereinafter, the semiconductor device according to a second embodiment will be described with reference to FIG. 15. FIG. 15 is a main portion cross-sectional view showing the interlayer insulating film IL4 and its upper layer and corresponding to the B-B line cross section of FIG. 3. Note that the third wiring M3 and its lower layer are the same as those in the first embodiment, and therefore will be omitted. Further, a plan view of a main part of the semiconductor device in the second embodiment is same as that of the first embodiment, and therefore plan view thereof is omitted.

As shown in FIG. 15, in the second embodiment, a structure of the groove GR in which a part of the pad electrode PAD is removed is formed between the inner peripheral edge of the opening OP and the outer peripheral edge of the bonding region BAR is similar to that of the first embodiment. However, the groove GR of the second embodiment is different from the first embodiment in that they reach the conductive film AL but do not penetrate the conductive film AL. That is, the groove GR does not reach the upper surface of the first barrier metal film BM1.

In the second embodiment, a depth of the groove GR is, for example, about ½ to ⅔ of a film thickness of the conductive film AL. The remaining of the conductive film AL is not divided by the groove GR, it is connected.

(Manufacturing Method of the Semiconductor Device According to the Second Embodiment)

Manufacturing method of the semiconductor device according to the second embodiment is similar as manufacturing method of semiconductor device for the first embodiment. However, manufacturing method of the second embodiment is different from manufacturing method of the first embodiment in that it does not penetrate the conductive film AL and does not expose the upper surface of the first barrier metal film BM1 when dry etching is performed using the second surface protective film IF2 as a mask.

(Effects of the Second Embodiment)

The impact applied to the end portion of the pad electrode PAD during wire bonding is transmitted by elastically deforming the conductive film AL in the horizontal direction. Then, the impact is transmitted mainly through a vicinity of the upper surface of the conductive film AL. Therefore, even in a structure that does not penetrate the conductive film AL as in the groove GR of the second embodiment, the groove GR has a function of blocking the impact applied to the end portion of the pad electrode PAD.

And a part of the side surfaces of the conductive film AL are released by the groove GR. Thus, the conductive film AL has a structure that can be elastically deformed in the horizontal direction. Therefore, also in the second embodiment, by absorbing the impact applied during wire bonding by elastic deformation, it is possible to reduce the transmission of the impact in the thickness direction of the conductive film AL.

Furthermore, since the groove GR of the second embodiment has the structure that does not penetrate the conductive film AL, the conductive film AL is not divided by the groove GR. That is, a bottom surface of the conductive film AL and the upper surface of the first barrier metal film BM1 are connected to face each other over the entire surface of the pad electrode PAD. With this structure, it is possible to prevent the pad electrode PAD from peeling at the interface between the bottom surface of the conductive film AL and the upper surface of the first barrier metal film BM1 when the conductive film AL elastically deforms during wire bonding.

### Third Embodiment

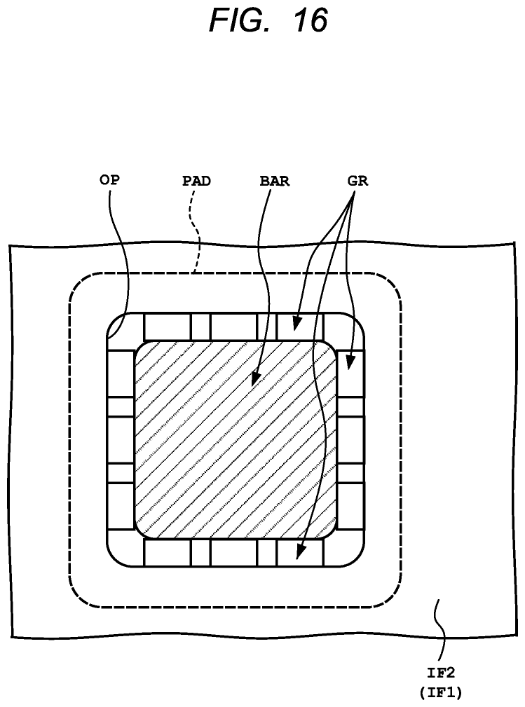

Hereinafter, the semiconductor device according to a third embodiment will be described with reference to FIG. 16. FIG. 16 is a main portion plan view showing the pad electrode PAD and its periphery of semiconductor device according to the third embodiment. Main portion cross-sectional view of the semiconductor device according to the third embodiment is same as that of the first embodiment, and therefore cross-sectional view thereof is omitted.

As shown in FIG. 16, in the third embodiment, a structure of the groove GR in which a part of the pad electrode PAD is removed is formed between the inner peripheral edge of the opening OP and the outer peripheral edge of the bonding region BAR is similar to that of the first embodiment. However, the groove GR is not formed so as to completely surround the outer peripheral edge of the bonding region BAR in a plan view. That is, the groove GR of the third embodiment is different from the first embodiment in that a plurality of grooves GR are formed between the inner peripheral edge of the opening OP and the outer peripheral edge of the bonding region BAR at a predetermined interval. In addition, the groove GR is different from the first embodiment in that it is not formed at each corner of the opening OP.

That is, the plurality of grooves GR of the third embodiment extends in the first direction extending along the outer peripheral edge of the bonding region BAR and are arranged at the predetermined interval in the second direction perpendicular to the first direction.

Here, in the third embodiment, an example is shown in which the plurality of grooves GR are formed for each of four sides of the opening OP, but a structure is not limited to this, and for example, the plurality of grooves GR may be formed one for each of the four sides of the opening OP and may not be connected at each corner of the opening OP.

### Fourth Embodiment

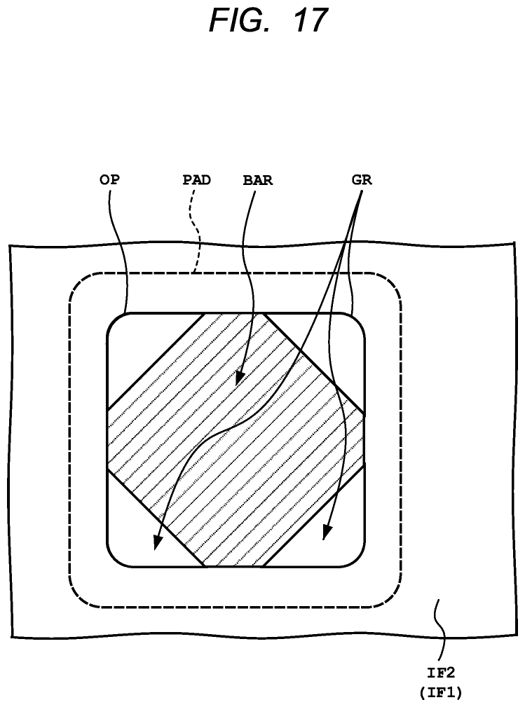

Hereinafter, the semiconductor device according to a fourth embodiment will be described with reference to FIG. 17. FIG. 17 is a main portion plan view showing the pad electrode PAD and its periphery of semiconductor device according to the fourth embodiment. Main portion cross-sectional view of the semiconductor device according to the fourth embodiment is same as that of the first embodiment, and therefore cross-sectional view thereof is omitted.

As shown in FIG. 17, in the fourth embodiment, the structure of the groove GR in which a part of the pad electrode PAD is removed is formed between the inner peripheral edge of the opening OP and the outer peripheral edge of the bonding region BAR is similar to that of the first embodiment. However, the groove GR is not formed so as to completely surround the outer peripheral edge of the bonding region BAR in a plan view. That is, the groove GR of the fourth embodiment is different from the first embodiment in that it is formed at the corner of the opening OP and is not formed near a midpoint of each of the four sides of the opening OP.

That is, the groove GR of the fourth embodiment is formed in triangles in the corner of the opening OP. The triangle region defined two adjacent sides of the inner peripheral edge of the opening OP each other and a traversed imaginary line traversed two adjacent sides of the inner peripheral edge of the opening OP. In other ward, each triangle has intersection points. One is intersection point intersected two adjacent sides of the inner peripheral edge of the opening OP. Others are intersection points intersected an imaginary line and these two sides. The imaginary line is intersected so as to travers these two sides.

### Fifth Embodiment

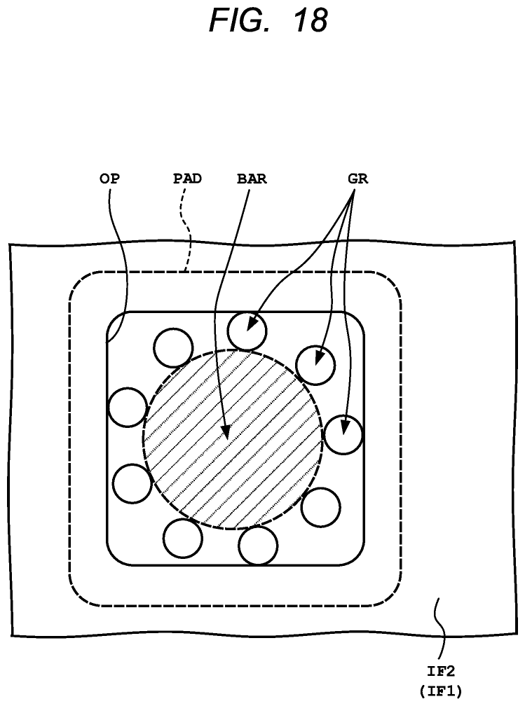

Hereinafter, the semiconductor device according to a fifth embodiment will be described with reference to FIG. 18. FIG. 18 is a main portion plan view showing the pad electrode PAD and its periphery of the semiconductor device according to the fifth embodiment. Main portion cross-sectional view of the semiconductor device according to the fifth embodiment is same as that of the first embodiment, and therefore cross-sectional view thereof is omitted.

As shown in FIG. 18, in the fifth embodiment, the structure of the groove GR in which a part of the pad electrode PAD is removed is formed between the inner peripheral edge of the opening OP and the outer peripheral edge of the bonding region BAR is similar to that of the first embodiment. However, the groove GR is not formed so as to completely surround the outer peripheral edge of the bonding region BAR in a plan view. That is, the groove GR of the fifth embodiment is different from the first embodiment in that a plurality of grooves GR are cylindrical through holes formed between the inner peripheral edge of the opening OP and the outer peripheral edge of the bonding region BAR at a predetermined interval.

(Effects of the Third, the Fourth and the Fifth Embodiments)

Also in the structures of the third, the fourth and the fifth embodiments, since the plurality of grooves GR is formed between the inner peripheral edge of the opening OP and the outer peripheral edge of the bonding region BAR, the plurality of grooves GR can reduce the impact applied during wire bonding. Then, it is possible to suppress the transmission of the impact to the first surface protective film IF1.

Further, the conductive film AL of the third, the fourth and the fifth embodiments, in a plan view, is not divided by the plurality of grooves GR. Therefore, as compared with the structure completely surrounding the periphery of the bonding region, it is possible to suppress a rigidity of the pad electrode PAD is reduced.

Although the invention made by the inventor has been specifically described based on the embodiments, the present invention is not limited to the embodiments described so far, and various modifications can be made without departing from the gist thereof.

For example, in each of the above embodiments, the region where the conductive film AL and the bonding wire BW is connected may be spaced apart from the outer peripheral edge of the bonding region BAR, it may coincide with the outer peripheral edge of the bonding region BAR. That is, the bonding wire BW may be connected to the conductive film AL so that its connecting end covers a portion of the groove GR.

Although the pad electrode PAD has been described a case in which a rectangular in plan view, a shape of the pad electrode PAD is not limited to the rectangular. That is, the shape of the pad chip PAD may be a polygon, such as eight squares, or may be a circle shape. By the shape of the pad electrode PAD and the polygonal or circular, it is possible to disperse the impact concentrated on corners of the pad electrode PAD during wire bonding.

What is claimed is:

1. A semiconductor device comprising:
a pad electrode;
a surface protective film covering the pad electrode and having an opening exposing a part of the pad electrode;
a bonding region located inside the opening in plan view; and
a first groove formed between an inner peripheral edge of the opening and an outer peripheral edge of the bonding region in plan view.

2. The semiconductor device according to claim 1, wherein
the first groove surrounds a periphery of the bonding region such that along the inner peripheral edge of the opening in plan view.

3. The semiconductor device according to claim 2, wherein
the pad electrode is a first laminated film in which a first metal film, a second metal film, and a third metal film are laminated in this order,
the second metal film is made of a material containing aluminum as a main component, and
the first metal film and the third metal film are made of materials containing titanium nitride as a main component.

4. The semiconductor device according to claim 3, wherein
the third metal film is removed in the opening and
the first groove penetrates the second metal film and reaches an upper surface of the first metal film.

5. The semiconductor device according to claim 4, wherein
a width of the first groove is 2 μm or more and 10 μm or less.

6. The semiconductor device according to claim 3, wherein
the third metal film is removed in the opening, and
the first groove reaches the second metal film and does not reach an upper surface of the first metal film.

7. The semiconductor device according to claim 6, wherein
a depth of the first groove is ½ or more and ⅔ or less of a thickness of the second metal film.

8. The semiconductor device according to claim 2, wherein
the surface protective film is a silicon oxide film or a silicon nitride film.

9. The semiconductor device according to claim 2, wherein
the surface protective film is a second laminated film in which a silicon oxide film or a silicon nitride film, and a polyimide film are laminated in this order.

10. A semiconductor device comprising:
a pad electrode;
a surface protective film covering the pad electrode and having an opening exposing a part of the pad electrode;
a bonding region located inside the opening in plan view; and
a plurality of second grooves formed between an inner peripheral edge of the opening and an outer peripheral edge of the bonding region in plan view, wherein
each of the plurality of second grooves extends in a first direction extending along the outer peripheral edge of the bonding region and are arranged at a predetermined interval in a second direction perpendicular to the first direction.

11. The semiconductor device according to claim 10, wherein
the plurality of second grooves formed in first regions in each corners of the opening, and
each of the first region is a triangle region defined two adjacent sides of the inner peripheral edge of the opening each other and a traversed imaginary line traversed two adjacent sides of the inner peripheral edge of the opening.

12. The semiconductor device according to claim 1, further comprising
a bonding wire connected to the bonding region, wherein
the bonding wire is electrically connected to the pad electrode in the bonding region.

13. The semiconductor device according to claim 12, further comprising
a sealing body sealing the pad electrode, the surface protective film and the bonding wire, wherein
the first groove is filled with the sealing body.

14. The semiconductor device according to claim 1, further comprising
an interlayer insulating film formed in contact with a bottom surface of the pad electrode, and
the interlayer insulating film is composed of a Low-k film.

15. The semiconductor device according to claim 1
a shape of the pad electrode is rectangular shape in plan view.

16. A manufacturing method of a semiconductor device, comprising the steps of:
(a) forming an interlayer insulating film on a main surface of a semiconductor substrate,
(b) forming a first laminated film in which a first metal film, a second metal film, and a third metal film are laminated in this order,
(c) forming a pad electrode by patterning the first laminated film,
(d) forming a surface protective film so as to cover the pad electrode,
(e) forming an opening by performing an etching the surface protective film and the third metal film, and exposing a part of the second metal film, and
(f) forming a first groove so as to penetrate the second metal film and reach an upper surface of the first metal film, wherein
the pad electrode has a bonding region located inside the opening in plan view; and
the first groove is arranged between an inner peripheral edge of the opening and an outer peripheral edge of the bonding region in plan view.

17. The manufacturing method of the semiconductor device according to claim 16, wherein
the first groove surrounds a periphery of the bonding region such that along the inner peripheral edge of the opening in plan view.

18. The manufacturing method of the semiconductor device according to claim 17, wherein
the second metal film is made of a material containing aluminum as a main component, and
the first metal film and the third metal film are made of materials containing titanium nitride as a main component.
